(19) United States
(12) Patent Application Publication
(10) Pub. No.: US 2013/0058082 A1
(43) Pub. Date: Mar. 7, 2013

(54) LINEAR LIGHT EMITTING DEVICE ASSEMBLIES INCLUDING CYLINDRICALLY SHAPED DIFFUSERS

(71) Applicants: Donald G. Hirsh, Chapel Hill, NC (US); Shawn Keeney, Chapel Hill, NC (US)

(72) Inventors: Donald G. Hirsh, Chapel Hill, NC (US); Shawn Keeney, Chapel Hill, NC (US)

(73) Assignee: Cree, Inc.

(21) Appl. No.: 13/227,042

(22) Filed: Sep. 7, 2011

(51) Int. Cl. F21V 5/00; H05K 13/00; F21S 4/00

(52) U.S. Cl. 362/235; 362/249.02; 29/592.1

(57) ABSTRACT

A light emitting device assembly can include a plurality of substrates, extending in a longitudinal direction, that are coupled together to provide a plurality of surfaces that face in respective radial directions that are orthogonal to the longitudinal direction. A heat sink can be coupled to the plurality of substrates, and the heat sink can extend radially from the plurality of substrates and is configured to transfer heat away from the plurality of substrates.

### FIELD OF THE INVENTION

The present invention relates to the field of electronics, and more particularly, to the field of light emitting diodes and assemblies related thereto.

### BACKGROUND

It is known to provide a linear array of light emitting diodes as a replacement for what is commonly referred to as a linear fluorescent lamp (LFL) used for general purpose lighting. For example, a linear array of light emitting diodes can be provided in a T8 or T5 format LFL. The quality of the light provided by many such linear array assemblies may, however, be unappealing in that the light fails to achieve a “smooth look” or otherwise does not meet the viewer's expectations.

### SUMMARY

Embodiments according to the invention can provide linear light emitting device assemblies including cylindrical diffusers. Pursuant to these embodiments, a light emitting device assembly can include a plurality of substrates, extending in a longitudinal direction, that are coupled together to provide a plurality of surfaces that face in respective radial directions that are orthogonal to the longitudinal direction. A heat sink can be coupled to the plurality of substrates, and extend radially from the plurality of substrates and is configured to transfer heat away from the plurality of substrates.

In some embodiments according to the invention, the assembly can further include a plurality of linear arrays of light emitting diodes, wherein each of the arrays is on a respective one of the plurality of surfaces, the arrays being configured to emit light in the radial directions. In some embodiments according to the invention, the assembly can further include a cylindrically shaped diffuser that extends in the longitudinal direction and at least partially encloses the plurality of substrates and is configured to diffuse the light from the arrays to a lighted space outside the diffuser.

In some embodiments according to the invention, the cylindrically shaped diffuser includes diffuser structures between an inner and an outer surface of the cylindrically shaped diffuser. In some embodiments according to the invention, the cylindrically shaped diffuser includes diffuser structures on an inner surface of the cylindrically shaped diffuser.

In some embodiments according to the invention, the plurality of linear arrays of light emitting diodes are spaced apart from the cylindrically shaped diffuser in radial directions by about 2 inches. In some embodiments according to the invention, the heat sink extends to outside the cylindrically shaped diffuser. In some embodiments according to the invention, the heat sink further includes a diffuser interface extending within an opening in the cylindrically shaped diffuser to receive opposing edges of the cylindrically shaped diffuser.

In some embodiments according to the invention, the plurality of substrates are coupled together with to define a triangular arrangement of the surfaces. In some embodiments according to the invention, the plurality of substrates are coupled together with flexible heat transfer tape. In some embodiments according to the invention, the plurality of substrates are coupled to the heat sink with flexible heat transfer tape.

In some embodiments according to the invention, a light emitting device assembly can include a plurality of printed circuit boards that extend in a longitudinal direction, coupled together to provide a plurality of surfaces facing in respective radial directions that are orthogonal to the longitudinal direction. A heat sink can be coupled to the plurality of printed circuit boards, extending radially from the plurality of printed circuit boards and can be configured to transfer heat away from the plurality of printed circuit boards. A cylindrically shaped diffuser can extend in the longitudinal direction to at least partially enclose the plurality of printed circuit boards.

In some embodiments according to the invention, a method of forming a light emitting device assembly can be provided by coupling a plurality of substrates together on a flexible heat transfer tape, the substrates having respective arrays of Light Emitting Diodes (LED) thereon to provide a preliminary LED assembly. The preliminary LED assembly can be folded so that opposing ends of the flexible heat transfer tape are coupled together to provide a polygonal arrangement. The polygonal arrangement can be coupled to a heat sink to provide an LED assembly.

In some embodiments according to the invention, the method can further include inserting the LED assembly into a cylindrically shaped diffuser. In some embodiments according to the invention, the preliminary LED assembly can be folded to provide a triangular arrangement.

### BRIEF DESCRIPTION OF THE DRAWINGS

FIG. 1A is a cross-sectional view of a light emitting device assembly in some embodiments according to the invention.

FIG. 1B is a perspective view of the light emitting device assembly shown in FIG. 1A.

FIG. 2 is a side view of a light emitting device assembly shown without a cylindrically shaped diffuser in some embodiments according to the invention.

FIG. 3 is a detailed view of a portion of a cylindrically shaped diffuser that can be used to enclose a light emitting device assembly in some embodiments according to the invention.

FIG. 4 is a flowchart illustrating methods of assembling light emitting device assemblies in some embodiments according to the invention.

FIG. 5 is a plan view of a plurality of printed circuit boards each including a linear array of light emitting diodes thereon coupled to flexible heat transfer tape in some embodiments according to the invention.

FIG. 6 is a cross-sectional view illustrating the plurality of printed circuit boards each having a linear array of light emitting diodes thereon coupled to the flexible heat transfer tape undergoing assembly into a triangular arrangement in some embodiments according to the invention.

FIG. 7 is a cross-sectional view illustrating the plurality of printed circuit boards each including a linear array of light emitting diodes thereon coupled to the flexible heat transfer tape undergoing assembly into a triangular arrangement in some embodiments according to the invention.

FIG. 8 is a cross-sectional view of the triangular arrangement of printed circuit boards and linear arrays of light emitting diodes thereon in a triangular arrangement coupled to the heat sink in some embodiments according to the invention.

### DETAILED DESCRIPTION OF EMBODIMENTS ACCORDING TO THE INVENTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Embodiments according to the invention are described herein with reference to conversion materials, wavelength conversion materials, phosphors, phosphor layers and related terms. The use of these terms should not be construed as limiting. It is understood that the use of the term phosphor, or phosphor layers is meant to encompass and be equally applicable to all wavelength conversion materials.

The term “color” as used herein with reference to light is meant to describe light having a characteristic average wavelength; it is not meant to limit the light to a single wavelength. Thus, light of a particular color (e.g., green, red, blue, yellow, etc.) includes a range of wavelengths that are grouped around a particular average wavelength.

As used herein, the term semiconductor light emitting diode may include a light emitting diode, laser diode and/or other semiconductor device which includes one or more semiconductor layers, which may include silicon, silicon carbide, gallium nitride and/or other semiconductor materials, a substrate which may include sapphire, silicon, silicon carbide and/or other microelectronic substrates, and one or more contact layers which may include metal and/or other conductive layers. In some embodiments, ultraviolet, blue and/or green light emitting diodes (“LEDs”) may be provided. Red and/or amber LEDs may also be provided. The design and fabrication of semiconductor light emitting diodes are well known to those having skill in the art and need not be described in detail herein.

The semiconductor LEDs packaged in accordance with embodiments of the invention may be gallium nitride-based LEDs fabricated on a silicon carbide substrate such as those devices manufactured and sold by Cree, Inc. of Durham, N.C.

In some embodiments according to the invention, a plurality of substrates can be coupled together in a polygonal arrangement so that a linear array of LEDs mounted on each of the respective faces of the substrates can emit light in radial directions, which may more closely approximate desirable lighting products. In some embodiments according to the invention, the polygonal arrangement can be a triangular arrangement.

Furthermore, the plurality of substrates can be formed into the polygonal arrangement using a flexible heat transfer tape, which can, in turn, be used to couple the polygonal arrangement of substrates to a heat sink that is configured to conduct heat away from the substrates. The heat sink can also include a diffuser interface. A cylindrically shaped diffuser can at least partially enclose the polygonal arrangement of both the substrates as well as a majority of the heat sink. In some embodiments according to the invention, opposing edges of the cylindrically shaped diffuser can be inserted into opposing ends of the diffuser interface.

In some embodiments according to the invention, the cylindrically shaped diffuser can have a diameter of about two inches. This diameter in conjunction with the LEDs arranged into linear arrays can allow the cylindrically shaped diffuser to include diffusion structures, for example, on a single side (such as the interior surface). This type of diffusion structure can provide more efficient diffusion and a smoother look for the light provided.

It will be understood that the substrates can be any structure suitable for carrying and operating the linear array of LEDs. For example, in some embodiments according to the invention, the substrates can be printed circuit boards including conductors that provide for the mounting of the LEDs, and for the signals and voltages appurtenant to the operation of the LEDs. In some embodiments according to the invention, the substrates can be a metal core board, FR4 board, a metal strip, such as aluminum, or other material or combination of these or other materials. The LEDs can be mounted on the substrate using, for example, thermal paste, adhesive and/or screws. In some embodiments according to the invention, the substrate can further include reflective surfaces to increase light extraction from the LEDs.

In some embodiments according to the invention, the substrates can be provided as a ceramic material such as a low temperature co-fired ceramic (LTCC) material. The LTCC material can be provided in what is sometimes referred to as green state ceramic tape formed of the ceramic materials, such as Al2O3, AlN, ZnO, or the like. In the green state, the LTCC material can be malleable, so as to be press-molded into various shapes. A leadframe structure can be, for example, pressed into an upper surface of the LTCC material, and then co-fired together to provide the substrate on which the LEDs can be mounted. The co-firing of the leadframe structure and the LTCC material, can cause constituent elements that comprise the leadframe structure and the LTCC material to mix with one another at, for example, a junction thereof so that the leadframe structure and the LTCC material become integrated. In some embodiments, the co-firing promotes chemical or covalent bonding of the materials therein to one another. In some embodiments according to the invention, the LTCC material and the leadframe structure are pressed together and heated together so that constituent elements of the LTCC material and the leadframe structure become integrated by mixing with one another. In some embodiments according to the invention, the LTCC material alone can be used to provide the substrate.

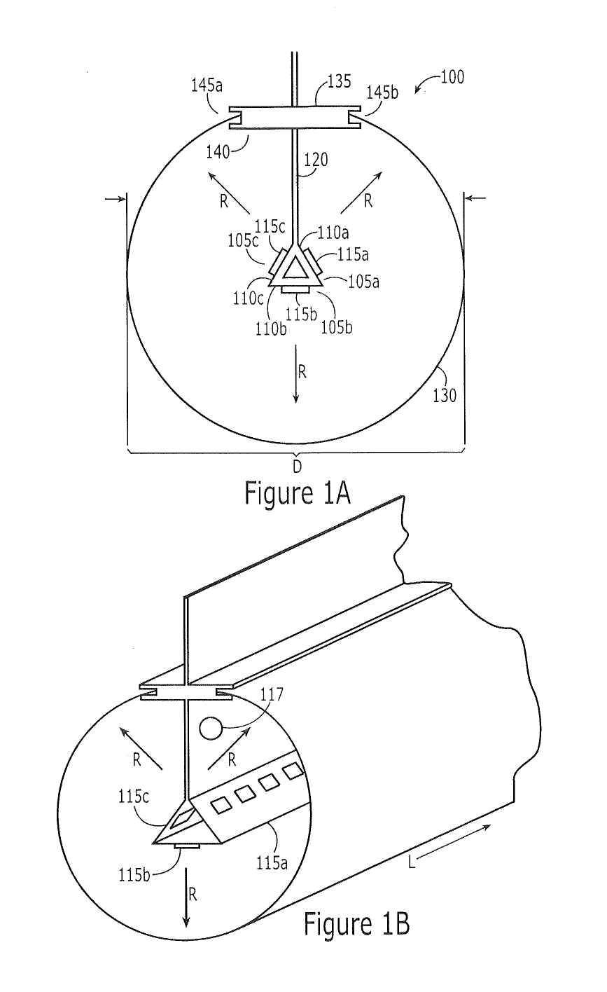

FIG. 1A is a cross-sectional view of a light emitting device assembly 100 in some embodiments according to the invention. FIG. 1B is a perspective view of the light emitting device assembly 100 shown in FIG. 1A. As shown in FIG. 1, a plurality of printed circuit boards 105A-C are coupled together to provide a plurality of respective surfaces 110A-C which face in respective radial directions away from a center of the light emitting device assembly 100. As shown in FIG. 1B, the plurality of printed circuit boards extend in a longitudinal direction L.

Each of the printed circuit boards 105A-C includes a respective linear array of LEDs 115A-C mounted thereon and configured to emit light in the radial directions R. The plurality printed circuit boards 105A-C and the linear arrays of LEDs 115A-C mounted thereon are in a triangular arrangement so that each of the surfaces estimates a side of an isosceles triangle. Therefore, as appreciated by the present inventors, the linear arrays of LEDs 115A-C provided in the triangular arrangement shown can provide a more pleasing distribution of light. It will be understood that the printed circuit boards can be arranged in any polygonal shaped arrangement sufficient to distribute the emitted light. The triangular arrangement is configured so that the array 105B faces away from the heat sink, whereas the other arrays 105A and 105C face in directions defined by the angles provided by the positions the remaining sides of the triangular arrangement. In some embodiments according to the invention, the triangular arrangement is configured so that the arrays 105A-C face directions at angles relative to one another defined by the triangular arrangement being an isosceles triangle.

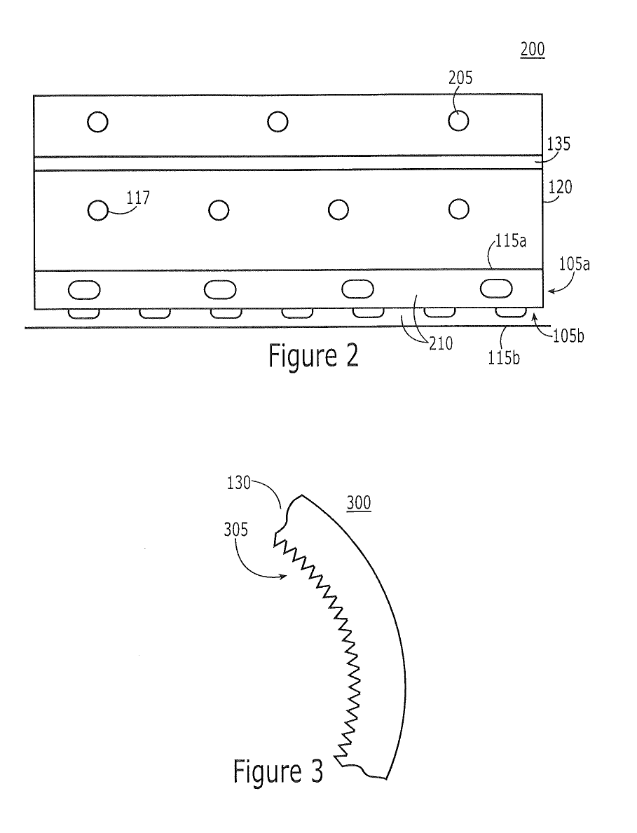

The triangular arrangement of printed circuit boards 105A-C and the linear arrays of LEDs 115A-C mounted thereon are coupled to a heat sink 120 which extends in the longitudinal direction as well as in the radial direction R that is orthogonal to the longitudinal direction L. The heat sink 120 also includes a diffuser interface 135 that provides openings at opposing ends thereof. The heat sink 120 further includes an external portion which can allow the light emitting device assembly 100 to be secured to another structure. As shown in FIG. 2, the heat sink 120 can include a void 205 in the external portion beyond the diffuser interface 135, which may be used to mechanically secure the LED assembly 200.

In some embodiments according to the invention, the heat sink 120 is any thermally efficient material sufficient to conduct heat away from the printed circuit boards 105A-C. For example, the heat sink 120 can be a metal, such as aluminum. In some embodiments according to the invention, the heat sink 120 is graphite. In some embodiments according to the invention, the heat sink 120 includes reflective surfaces to improve light extraction. In some embodiments according to the invention, the heat sink 120 is a unitary structure, and also provides the polygonal shaped arrangement on which the linear arrays of LEDs are mounted (e.g., the triangular arrangement). In some embodiments according to the invention, the unitary polygonal shaped arrangement includes features on the faces configured to allow the linear arrays of LEDs to be fastened thereto. For example, the unitary polygonal shaped arrangement features may be configured to allow the substrates having the arrays thereon to snap, screw, or slide into place.

In some embodiments according to the invention, the triangular arrangement includes the void defined by the triangular arrangement. In some embodiments according to the invention, the triangular arrangement is solid such that no void is provided.

A cylindrically shaped diffuser 130 can be positioned to at least partially enclose the plurality of printed circuit boards 105A-C and the majority of the heat sink 120. In particular, opposing edges 145A and 145B of the cylindrically shaped diffuser can be inserted into the openings in the diffuser interface 135 of the heat sink 120. In some embodiments according to the invention, the cylindrically shaped diffuser 130 can have a diameter D of about 2 inches. In some embodiments according to the invention, the cylindrically shaped diffuser 130 can have a diameter D less than about 2 inches and greater than about 1.5 inches. In some embodiments according to the invention, the cylindrically shaped diffuser 130 can have a diameter D of less than about 1.5 inches and greater than about 1.0 inch. Other diameters can also be used.

Electrical conductors for operation of the linear arrays of LEDs 115A-C can be provided, for example, via the ends of the cylindrically shaped diffuser 130. Electrical conductors can also be provided via the heat sink 120. As further shown in FIG. 1B, the heat sink 120 can include holes 117, which can promote air flow for more efficient heat transfer by the heat sink 120 from LEDs 115.

FIG. 2 is a side view of a light emitting device assembly 200 without the cylindrically shaped diffuser 130 shown in FIG. 1, in some embodiments according to the invention. According to FIG. 2, the LEDs included in the linear arrays of LEDs 115A-C can be spaced apart on the plurality of printed circuit boards 105A-C at different pitches. For example, a first spacing between the LEDs included in the first linear array of LEDs 115A can be greater than a second spacing of the LEDs included in the second linear array of LEDs 115B. In some embodiments according to the invention, the LEDs can be spaced apart by a distance of about 1.8 cm to about 1.1 cm. In some embodiments, the LEDs can be spaced apart by a variable amount. In some embodiments, the LEDs can be spaced apart by an amount that is based on the package sizes of the particular LEDs. Other spacing may be used.

In some embodiments the LEDs represent clusters of discrete LEDs, with each LED within the cluster spaced a distance from the next LED in that cluster, and each cluster spaced a distance from the next cluster. If the LEDs within a cluster are spaced at too great distance from one another, the colors of the individual LEDs may become visible, causing unwanted color-striping. In some embodiments, an acceptable range of distances for separating consecutive LEDs within a cluster is not more than approximately 8 mm.

In some embodiments according to the invention, the LEDs in the arrays can be XLamp ML-B or ML-E LEDs available from Cree, Inc. of Durham N.C., or a combination of different LEDs. In some embodiments according to the invention, the LEDs may be rated at about 0.5 W to about 0.25 W.

The arrays can include LEDs producing the same color of light or different colors of light. In some embodiments, a multicolor source LED is used to produce white light. Several colored light combinations will yield white light. For example, light from a blue LED can be combined with wavelength-converted yellow (blue-shifted-yellow or “BSY”) light to yield white light with correlated color temperature (CCT) in the range between 5000K to 7000K (often designated as “cool white”). Both blue and BSY light can be generated with a blue emitter by surrounding the emitter with phosphors that are optically responsive to the blue light. When excited, the phosphors emit yellow light which then combines with the blue light to make white. In this scheme, because the blue light is emitted in a narrow spectral range it is called saturated light. The BSY light is emitted in a much broader spectral range and, thus, is called unsaturated light.

In some embodiments, white light can be generated using a multicolor source by combining light from green and red LEDs. RGB schemes may also be used to generate various colors of light. In some applications, an amber emitter is added for an RGBA combination. The previous combinations are exemplary; it is understood that many different color combinations may be used in embodiments of the present invention. Several of these possible color combinations are discussed in detail in U.S. Pat. No. 7,213,940 to Van de Ven et al., which is incorporated herein by reference.

The arrays of LEDs each represent possible LED combinations that result in an output spectrum that can be mixed to generate white light. Each array can include the electronics and interconnections necessary to power the LEDs.

FIG. 3 is a detailed view of a portion of the cylindrically shaped diffuser 130 in some embodiments according to the invention. As shown in FIG. 3, a diffusion pattern 305 can be stamped or otherwise replicated onto an interior surface of the cylindrically shaped diffuser 130. Placing the diffusion structure 305 only on the interior surface may provide adequate diffusion of the light provided by the linear arrays of LEDs. Further, locating the diffusion structure 305 on the interior surface may reduce the need for cleaning to maintain proper diffusion, as the interior surface is less likely to be handled during assembly or maintenance and may therefore guard against degrading the diffusion. Still further, the diffusion structure 305 on the interior surface may provide a smoother and more efficient light distribution when used in conjunction with the LED assemblies described herein and particularly, when the plurality of printed circuit boards 105A-C are placed in a triangular arrangement at about the center of the cylindrical shaped diffuser 130 having a diameter of about 2 inches.

In some embodiments according to the invention, the cylindrically shaped diffuser 130 comprises an optically clear material, such as glass, with a diffusion material coating on a surface of the optically clear material. In some embodiments according to the invention, the interior surface of the optically clear material is coated with the diffusion material. In some embodiments according to the invention, the exterior surface of the optically clear material is coated with the diffusion material. In some embodiments according to the invention, the interior and exterior surfaces of the optically clear material are coated with the diffusion material. In some embodiments according to the invention, the diffusion material is embedded or suspended within the cylindrically shaped diffuser 130.

In some embodiments according to the invention, a diffusive film inlay can be applied to the interior or exterior surface of the cylindrically shaped diffuser 130. In some embodiments according to the invention, the cylindrically shaped diffuser 130 can be formed to include an integral diffusive layer, such as by coextruding the two materials or insert molding the diffuser onto the exterior or interior surface. A diffractive or repeated geometric pattern may be rolled into an extrusion or molded into the surface at the time of manufacture. In another embodiment, the cylindrically shaped diffuser 130 itself may comprise a volumetric diffuser, such as an added colorant or particles having a different index of refraction, for example.

In some embodiments according to the invention, cylindrically shaped diffuser 130 can include a single multilayer film. In other embodiments according to the invention, the cylindrically shaped diffuser 130 can include a plurality of multi-layer films that can provide additive diffusion properties. In some embodiments according to the invention the cylindrically shaped diffuser 130 can be a polyester film having microreplicated structures on their surface, produced through a photoreplication process. The polyester film can include a photopolymer with refractive index of about 1.55.

In some embodiments according to the invention, the cylindrically shaped diffuser 130 can comprise a wavelength conversion material coated on a surface, such as the interior or exterior surface. For example, a phosphor can be coated onto the exterior surface so that light that propagates through the cylindrically shaped diffuser 130, is shifted to provide a white light. In some embodiments according to the invention, therefore, the phosphor is remote from the LEDs in the arrays.

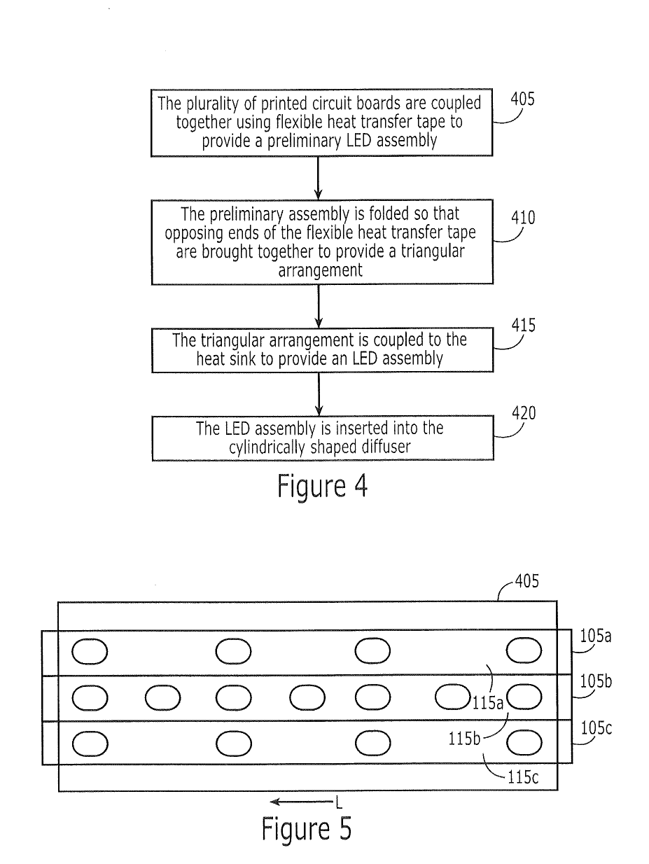

FIG. 4 is a flow chart illustrating methods of assembling an LED assembly in some embodiments according to the invention. FIGS. 5-8 are schematic views illustrating assembly of LED assemblies in some embodiments according to the invention. FIG. 5 is a plan view of the plurality of printed circuit boards 105A-C, each including a respective linear array of LEDs 115A-C mounted thereon. Referring to FIGS. 4-8, the plurality of printed circuit boards 105A-C are coupled together using flexible heat transfer tape 505 to provide a preliminary LED assembly 500 (block 405 of FIG. 4). It will be understood that the flexible heat transfer tape 505 can be any material with adhesion sufficient to couple the plurality of printed circuit boards 105A-C together and provide sufficient thermal conductivity. For example, in some embodiments according to the invention, the flexible heat transfer tape 505 can be GRAFIHX™, available from GraphTech, International of Lakewood, Ohio. In still other embodiments according to the inventive concept, the plurality of printed circuit boards 105A-C can be LTCC material, with or without the flexible heat transfer tape 505.

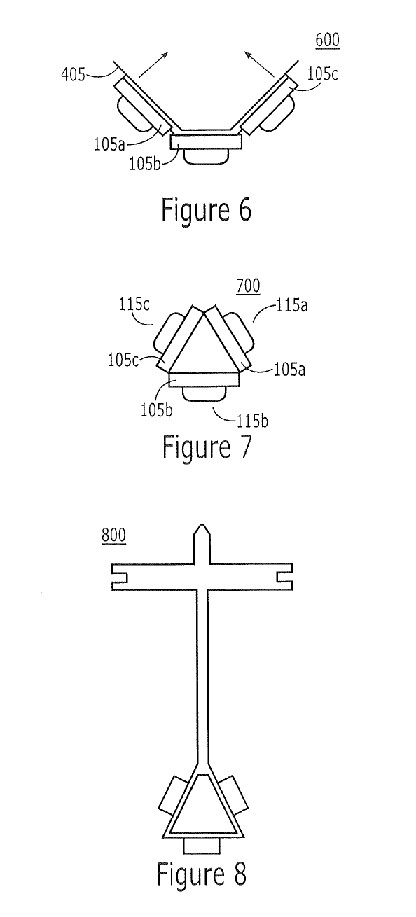

The preliminary assembly 500 is folded so that opposing ends of the flexible heat transfer tape 505 are brought together (FIG. 6) to provide a triangular arrangement 700 as shown in FIG. 7 (block 410 of FIG. 4). In still other embodiments according to the inventive concept, the plurality of printed circuit boards 105A-C is green state tape, and the flexible heat transfer tape 505 may be eliminated so that the green state tape (with the LEDs thereon) is folded to provide the triangular arrangement 700, which is co-fired to provide the triangular arrangement 700 on the LTCC material.

The triangular arrangement 700 is coupled to the heat sink 120 to provide an LED assembly 800 shown in FIG. 8 (block 415 of FIG. 4). In some embodiments according to the invention, a remaining portion of the flexible heat transfer tape 505 is used to adhere the triangular arrangement 700 to the heat sink 120. In still other embodiments according to the invention, when the triangular arrangement 700 is in a green state, the triangular arrangement 700 can be contacted to the heat sink 120 and co-fired therewith to secure the triangular arrangement 700 the heat sink 120. The LED assembly 800 in FIG. 8 is inserted into the cylindrically shaped diffuser 130 (Block 420 of FIG. 4) to provide the structure shown in FIG. 1.

As described herein, in some embodiments according to the invention, a plurality of substrates can be coupled together in a polygonal arrangement so that a linear array of LEDs mounted on each of the respective faces of the substrates can emit light in radial directions, which may more closely approximate desirable lighting products. In some embodiments according to the invention, the polygonal arrangement can a triangular arrangement.

Furthermore, the plurality of substrates can be formed into the polygonal arrangement using a flexible heat transfer tape, which can, in turn, be used to couple the polygonal arrangement of substrates to a heat sink that is configured to conduct heat away from the substrates. The heat sink can also include a diffuser interface. A cylindrically shaped diffuser can at least partially enclose the polygonal arrangement of both substrates as well as a majority of the heat sink. In some embodiments according to the invention, opposing edges of the cylindrically shaped diffuser can be inserted into opposing ends of the diffuser interface.

In some embodiments according to the invention, the heat sink can be a unitary structure that is formed into the shape shown in FIG. 8, and can also include the triangular arrangement on which the linear arrays of LEDs (on the substrates) can then be mounted. In some embodiments according to the invention, the unitary triangular arrangement includes features on the faces configured to allow the substrates with the linear arrays of LEDs thereon to be fastened thereto. For example, the unitary triangular arrangement features may be configured to allow the substrates having the arrays thereon to snap, screw, or slide into place.

In some embodiments according to the invention, the cylindrically shaped diffuser can have a diameter of about two inches. This diameter in conjunction with the LEDs arranged into linear arrays can allow the cylindrically shaped diffuser to include diffusion structures, for example, on a single side (such as the interior surface). This type of diffusion structure can provide a more efficient diffusion and a smoother look for the light provided.

In the drawings and specification, there have been disclosed embodiments of the invention and, although specific terms are employed, they are used in a generic and descriptive sense only and not for purposes of limitation, the scope of the invention being set forth in the following claims.

What is claimed:

1. A light emitting device assembly comprising:
a plurality of substrates, extending in a longitudinal direction, coupled together to provide a plurality of surfaces facing in respective radial directions that are orthogonal to the longitudinal direction; and
a heat sink, coupled to the plurality of substrates, extending radially from the plurality of substrates and configured to transfer heat away from the plurality of substrates.

2. The assembly of claim 1 further comprising:
a plurality of linear arrays of light emitting diodes, wherein each of the arrays is on a respective one of the plurality of surfaces, the arrays being configured to emit light in the radial directions.

3. The assembly of claim 2 further comprising:
a cylindrically shaped diffuser, extending in the longitudinal direction, at least partially enclosing the plurality of substrates and configured to diffuse the light from the arrays to a lighted space outside the diffuser.

4. The assembly of claim 3 wherein the cylindrically shaped diffuser includes diffuser structures between an inner and an outer surface of the cylindrically shaped diffuser.

5. The assembly of claim 3 wherein the cylindrically shaped diffuser includes diffuser structures on an inner surface of the cylindrically shaped diffuser.

6. The assembly of claim 3 wherein the plurality of linear arrays of light emitting diodes are spaced apart from the cylindrically shaped diffuser in radial directions by about 2 inches.

7. The assembly of claim 3 wherein the heat sink extends to outside the cylindrically shaped diffuser.

8. The assembly of claim 7 wherein the heat sink further comprises a diffuser interface extending within an opening in the cylindrically shaped diffuser to receive opposing edges of the cylindrically shaped diffuser.

9. The assembly of claim 1 wherein the plurality of substrates are coupled together with to define a triangular arrangement of the surfaces.

10. The assembly of claim 9 wherein the plurality of substrates are coupled together with flexible heat transfer tape.

11. The assembly of claim 10 wherein the plurality of substrates are coupled to the heat sink with flexible heat transfer tape.

12. A light emitting device assembly comprising:
a plurality of printed circuit boards, extending in a longitudinal direction, coupled together to provide a plurality of surfaces facing in respective radial directions that are orthogonal to the longitudinal direction;
a heat sink, coupled to the plurality of printed circuit boards, extending radially from the plurality of printed circuit boards and configured to transfer heat away from the plurality of printed circuit boards; and
a cylindrically shaped diffuser, extending in the longitudinal direction, at least partially enclosing the plurality of printed circuit boards.

13. The assembly of claim 12 further comprising:
a plurality of linear arrays of light emitting diodes, wherein each of the arrays is on a respective one of the plurality of surfaces, the arrays being configured to emit light in the radial directions.

14. The assembly of claim 12 wherein the heat sink further comprises a diffuser interface extending within an opening in the cylindrically shaped diffuser to receive opposing edges of the cylindrically shaped diffuser.

15. The assembly of claim 12 wherein the plurality of printed circuit boards are coupled together to define a triangular arrangement of the surfaces.

16. The assembly of claim 12 wherein the plurality of printed circuit boards are coupled together with flexible heat transfer tape.

17. The assembly of claim 16 wherein the plurality of printed circuit boards are coupled to the heat sink with flexible heat transfer tape.

18. A method of forming a light emitting device assembly, the method comprising:
coupling a plurality of substrates together on a flexible heat transfer tape, the substrates having respective arrays of Light Emitting Diodes (LED) thereon to provide a preliminary LED assembly;
folding the preliminary LED assembly so that opposing ends of the flexible heat transfer tape are coupled together to provide a polygonal arrangement; and
coupling the polygonal arrangement to a heat sink to provide an LED assembly.

19. The method of claim 18 further comprising:
inserting the LED assembly into a cylindrically shaped diffuser.

20. The method of claim 18 wherein folding the preliminary LED assembly so that opposing ends of the flexible heat transfer tape are coupled together to provide the polygonal arrangement comprises folding the preliminary LED assembly so that opposing ends of the flexible heat transfer tape are coupled together to provide a triangular arrangement.
